(19) United States
(12) Patent Application Publication
(10) Pub. No.: US 2025/0309845 A1
(43) Pub. Date: Oct. 2, 2025

(54) AMPLIFIER WITH IMPEDANCE-SETTING CIRCUIT

(71) Applicant: Texas Instruments Incorporated, Dallas, TX (US)

(72) Inventors: Arun Singh, Bangalore (IN); Mahadevan Venkiteswaran, Bangalore (IN); Jofin V, Bangalore (IN); Ravpreet Singh, Bangalore (IN)

(21) Appl. No.: 18/901,344

(22) Filed: Sep. 30, 2024

(30) Foreign Application Priority Data
Apr. 1, 2024 (IN) 202441026983

(51) Int. Cl. H03F 3/45; H03F 1/08; H03F 1/32; H03F 3/50

(52) U.S. Cl. CPC H03F 3/4508; H03F 3/50; H03F 1/083; H03F 1/3211

(57) ABSTRACT

In described examples, a circuit includes a first current source, a second current source, a first bipolar junction transistor (BJT), a second BJT, a third BJT, a fourth BJT, and a fifth BJT. A base of the second BJT is coupled to a first terminal of the first current source. A base of the third BJT is coupled to a first terminal of the second current source, and an emitter of the third BJT is coupled to an emitter of the second BJT and a collector of the first BJT. A base of the fifth BJT is coupled to a base and an emitter of the fourth BJT and to a collector of the third BJT, and a collector of the fifth BJT is coupled to an emitter of the first BJT.

### CROSS-REFERENCE TO RELATED APPLICATION

This application claims the benefit of and priority to India Provisional Application No. 202441026983, filed Apr. 1, 2024, which is incorporated herein by reference.

### TECHNICAL FIELD

This application relates generally to amplifiers, and more particularly to an amplifier controlled using an emitter follower.

### BACKGROUND

In an amplifier or other circuit, a differential transconductance amplifier input stage can drive an intermediate stage bipolar junction transistor (BJT) that is connected as an emitter follower. The intermediate stage BJT provides a current to drive a second, output stage BJT. The output stage BJT provides a current drive capability to the amplifier, and also provides a feedback voltage to the differential input stage to tune the current that drives the amplifier. Characteristic properties of the circuit include direct current (DC) loop gain, phase margin, and a maximum load capacitance that the circuit can drive stably. In some examples, instability corresponds to a zero phase margin, which can cause sustained spurious oscillations at the output that do not correspond to designed gain. In some examples, zero phase margin causes the output voltage of the circuit to swing to a supply voltage or a ground voltage and not recover to an output voltage corresponding to designed gain.

### SUMMARY

In described examples, a circuit includes a first current source, a second current source, a first bipolar junction transistor (BJT), a second BJT, a third BJT, a fourth BJT, and a fifth BJT. A base of the second BJT is coupled to a first terminal of the first current source. A base of the third BJT is coupled to a first terminal of the second current source, and an emitter of the third BJT is coupled to an emitter of the second BJT and a collector of the first BJT. A base of the fifth BJT is coupled to a base and an emitter of the fourth BJT and to a collector of the third BJT, and a collector of the fifth BJT is coupled to an emitter of the first BJT.

In described examples, a circuit includes a first stage, a second stage, and a third stage. The second stage includes a first current source, a second current source, and first, second, third, fourth, and fifth BJTs. A base of the first BJT is coupled to an output of the first stage. A base of the second BJT is coupled to a first terminal of the first current source. A base of the third BJT is coupled to the first terminal of the second current source, and an emitter of the third BJT is coupled to an emitter of the second BJT and a collector of the first BJT. A base of the fifth BJT is coupled to a base and an emitter of the fourth BJT and to a collector of the third BJT. A collector of the fifth BJT is coupled to an emitter of the first BJT. An input of the third stage is coupled to the emitter of the first BJT, and an output of the third stage is coupled to an input of the first stage.

In described examples, a circuit includes an emitter follower-connected (EFC) bipolar junction transistor (BJT) and an impedance-setting circuit. A first terminal of the impedance-setting circuit is coupled to a collector of the EFC BJT, and a second terminal of the impedance-setting circuit is coupled to an emitter of the EFC BJT. The impedance-setting circuit is configured to compare a first current to a threshold, and to, responsive to the comparison, either provide a second current to the collector of the EFC BJT or provide a third current to the collector of the EFC BJT and provide a fourth current to the emitter of the EFC BJT.

### BRIEF DESCRIPTION OF THE DRAWINGS

FIG. 1 is a circuit diagram of an amplifier system with an amplifier, an impedance-setting stage, and a load.

FIG. 2 is a circuit diagram of a second amplifier.

FIG. 3 is a circuit diagram of a third amplifier.

FIG. 4 is a circuit diagram of an amplifier system.

FIG. 5 is a circuit diagram of a circuit for generating a β-dependent current.

FIG. 6 is an example process for detecting fabrication process variation in a BJT.

### DETAILED DESCRIPTION

An amplifier for driving a load may have multiple stages for DC gain, and the gain of at least one stage may vary with one or more of process or temperature variation. In an example, the amplifier includes an impedance setting circuit to reduce undesirable effects of stage gain variance. The impedance setting circuit may adjust intermediate stage impedance based in part on a comparison between a reference current and a current responsive to the gain of a BJT of the intermediate stage.

In one example, the impedance setting circuit includes a collector-emitter path of a second BJT that is coupled in parallel with the intermediate stage BJT and driven by a fixed voltage. In some examples, a current through the collector-emitter path of the second BJT limits or reduces the output impedance of the input stage. This improves (for example, increases) phase margin and support for high (or infinite) load capacitance in response to process and temperature variation of current gain of the intermediate stage BJT. In particular, the second BJT improves circuit stability with respect to BJT current gain that is greater than a designed value, such as due to process or temperature variation.

In an example, an impedance-setting circuit is coupled to selectively provide (steer) a current to a collector of the intermediate stage BJT. A current is generated in response to the current gain (β) of the intermediate stage BJT, referred to herein as a β-dependent current. The provided current is in response to a comparison between the β-dependent current and a threshold.

If current gain is high, so that the β-dependent current is less than the threshold, the impedance-setting circuit provides a first current to the collector of the intermediate stage BJT. The first current is responsive to the β-dependent current. This prevents an output impedance of the input stage from rising above a designed value responsive to current gain greater than a designed value. This limitation on output impedance of the input stage improves circuit stability.

If current gain is low, so that the β-dependent current is greater than the threshold, the impedance-setting circuit provides a second current to the collector of the intermediate stage BJT and provides a third current to the emitter of the intermediate stage BJT. The second and third currents are responsive to a reference current. The provided second and third currents set a floor on a current biasing the output stage BJT, which improves reliability of DC loop gain of the circuit.

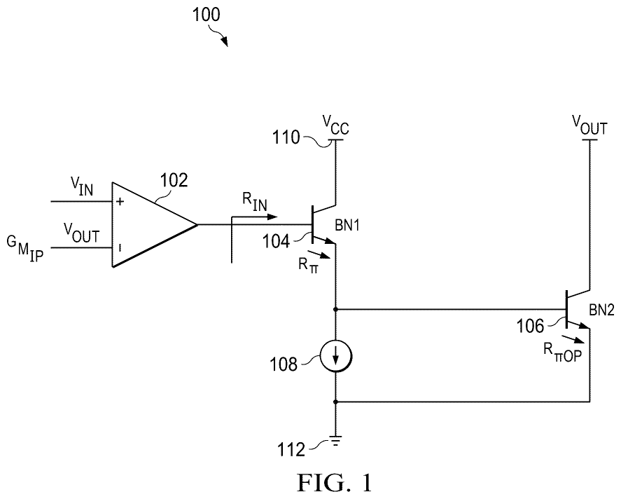

FIG. 1 is a circuit diagram of an amplifier 100, such as an op-amp. The amplifier 100 includes a first stage 102 (such as an input stage 102), a first NPN BJT (BN1) 104, a second NPN BJT (BN2) 106, a current source 108, a voltage source 110, and a ground 112.

A non-inverting input of the first stage 102 receives an input voltage V_{IN} at an input of the amplifier 100, corresponding to a control signal of the amplifier 100. An inverting input of the first stage 102 is coupled to a collector of BN2 106 to receive an output voltage V_{OUT}, corresponding to a feedback signal. An output of the first stage 102 is coupled to a base of BN1 104.

An emitter follower, also called a common collector amplifier, has a base that is coupled to an input of the circuit, an emitter that is coupled to an output of the circuit, and a collector. The base receives a bias signal. The emitter provides an output signal responsive to the bias signal, and the collector receives a signal that shows little or no change responsive to changes to the signal received by the base or the signal provided at the emitter. In some examples, the collector is coupled to a voltage source at a voltage source terminal or to ground at a ground terminal. A collector of BN1 104 is coupled to the voltage source 110, and an emitter of BN1 104 is coupled to a base of BN2 106 and a first terminal of the current source 108. Accordingly, BN1 104 is coupled as an emitter follower. An emitter of BN2 106 and a second terminal of the current source 108 are coupled to ground 112. In the illustrated example, a differential transconductance amplifier is a first stage 102 of the amplifier 100, BN1 104 is an intermediate stage of the amplifier 100, and BN2 106 is an output stage of the amplifier 100.

In some examples, increasing a first stage 102 output impedance of an amplifier increases a DC open loop gain of the amplifier. In some examples, the gain of the amplifier is related to a product of series-coupled transconductances and output impedances (such as resistances) of the transconductances in the amplifier (such as gₘ₁ times R₁ times gₘ₂ times R₂, etc.). In some examples that do not include an intermediate stage (BN1 104), the first stage 102 provides the base current for the output stage transistor(s) (BN2 106). The first stage 102 providing current to the output stage (BN2 106) lowers the output impedance of the first stage 102, which lowers the DC loop gain of the amplifier 100.

The emitter of BN1 104 provides a base current for the output stage of the amplifier 100, accordingly, BN2 106. Accordingly, including BN1 104 as an intermediate stage to provide the base current for BN2 106 increases DC loop gain of the amplifier 100, as further described below.

The current gain β of a BJT equals the collector current of the BJT divided by the base current of the BJT. In Equations 1 through 3, and as described above, β equals the current gains of each of BN1 104 and BN2 106 while BN1 104 and BN2 106 are operating in the forward active mode, μm is the transconductance of BN2 106 (the output stage transconductance), Rx is the base-emitter impedance of BN1 104 (the emitter-follower), and RzOP is the base-emitter impedance of BN2 106 (the output transistor). R_{IN} equals the output impedance of the first stage 102 in parallel with the input impedance of the second stage (BN1 104). Recall that total resistance of two resistances R1 and R2 coupled in parallel equals R1×R2/(R1+R2). In some examples, the input impedance of BN1 104 is sufficiently smaller than the output impedance of the first stage 106 that the input impedance of BN1 104 dominates R_{IN}. With respect to β, the current gains of BN1 104 and BN2 106 are treated as equal because they are fabricated to avoid process and temperature variation between BN1 104 and BN2 106. Also, variations in β relating to different current densities through BN1 104 and BN2 106 are sufficiently small as to be negligible for modeling purposes. Equations 1 through 3 show that R_{IN} is related to the square of β:

$${R}_{IN} = {R}_{π} + β \times {R}_{π OP} \qquad Equation 1$$

$${R}_{IN} = {R}_{π} + β \times \frac{β}{{g}_{m}} \qquad Equation 2$$

$${R}_{IN} \approx \frac{{β}^{2}}{{g}_{m}} \qquad Equation 3$$

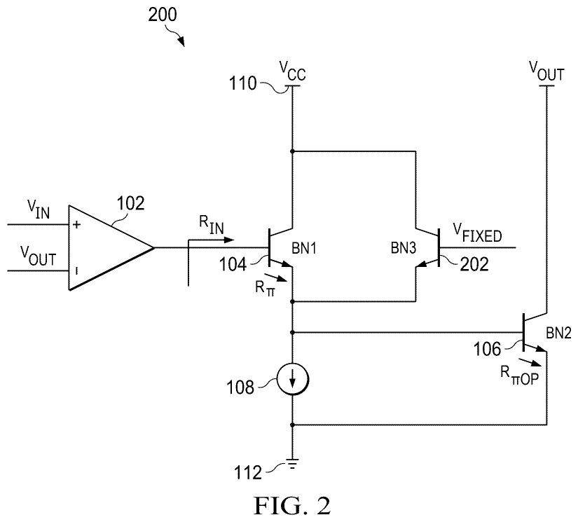

Accordingly, in the illustrated example, increasing β of BN1 104 and BN2 106 increases an effective output impedance of the first stage 102, as seen by the output stage (BN2 106). However, in some examples, β can be sensitive to manufacturing process variation and temperature variation. Because the first stage output impedance has a second-order relationship to β, first stage output impedance can increase quickly in response to increasing β. Limiting a slope of the relationship between first stage output impedance with respect to β enables the amplifier 100 to stably drive high capacitance loads with improved phase margin across process corners and temperature variation. In some examples, phase margin is greater than 15 degrees. An amplifier 200 that limits a rate of increase of first stage output impedance with respect to increasing β is further described with respect to FIG. 2.

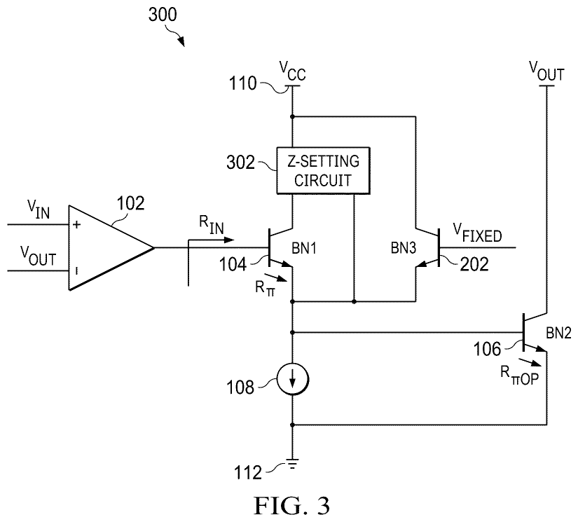

As described above, process and temperature variations that cause β to decrease can reduce DC loop gain. An amplifier system 300 that improves (for example, increases) first stage output impedance at a low end is further described with respect to FIG. 3.

FIG. 2 is a circuit diagram of a second amplifier 200, such as an op-amp. The amplifier 200 includes a third NPN BJT (BN3) 202. A collector of BN3 202 is coupled to the voltage source 110. An emitter of BN1 104 is coupled to an emitter of BN3 202, the base of BN2 106, and the first terminal of the current source 108. A base of BN3 202 receives a constant bias voltage VFIXED so that the emitter of BN3 202 provides a constant bias current to the base of BN2 106 while the amplifier 200 has little or no load current.

If there is little or no load current, a looking in impedance of the output stage (BN2 106) may become relatively high, potentially causing instability. Current provided by BN3 202 reduces or limits the looking in impedance of BN1 104. The looking in impedance of BN1 104 corresponds to an impedance at the emitter of BN3 202 in parallel with an impedance at the base of BN2 106. Responsive to BN3 202 providing current, the impedance at the emitter of BN3 202 is significantly smaller than the impedance at the base of BN2 106, and accordingly dominates and decreases the looking in impedance of BN1 104. Reduction in looking in impedance of BN1 104 improves stability in an under-loaded or no-load condition by reducing a total impedance from the input stage 102 to the output stage (BN2 106).

This changes the relationship between β and input impedance R_{IN} from quadratic to linear. As described above, this reduces or limits increase of first stage 102 output impedance responsive to β. Accordingly, the amplifier 200 is less sensitive than the amplifier 100 to a process-related or temperature-related increase in β. The transconductance of BN1 104 is g_{mEF}, and the transconductance of BN3 202 is g_{mAUX}. Also, the current gains of BN1 104 and BN3 202 are treated as equal (β) because they are fabricated to avoid process and temperature variation between BN1 104 and BN3 202. The relationship between β and R_{IN} in the amplifier 200 is described by Equations 4 through 6:

$${R}_{IN} = {R}_{π} + β \times \frac{1}{{g}_{mAUX}} \qquad Equation 4$$

$${R}_{IN} = \frac{β}{{g}_{mEF}} + \frac{β}{{g}_{mAUX}} \qquad Equation 5$$

$${R}_{IN} = β \times ( \frac{1}{{g}_{mEF}} + \frac{1}{{g}_{mAUX}} ) \qquad Equation 6$$

Accordingly, a maximum β can be determined using Equation 6 and responsive to variability of β responsive to process and temperature (and other) variation. In particular, the maximum β can be determined to enable setting impedances of the amplifier 200 to improve stability in response to a wide range of load capacitance. In some examples, the amplifier 200 can be made highly stable in response to an infinite load capacitance.

FIG. 3 is a circuit diagram of a third amplifier 300, such as an op-amp. The amplifier 300 includes an impedance-setting (Z-setting) circuit 302. A first terminal of the Z-setting circuit 302 is coupled to the voltage source 110 and a collector of BN3 202. A second terminal of the Z-setting circuit 302 is coupled to a collector of BN1 104. A third terminal of the Z-setting circuit 302 is coupled to an emitter of BN1 104, an emitter of BN3 202, the base of BN2 106, and the first terminal of the current source 108.

The Z-setting circuit 302 performs a comparison between a β-dependent current and a reference current. Accordingly, the reference current can be described as a threshold. In some examples, the β-dependent current is inversely proportional to β, so that if β is high the β-dependent current is low, and if β is low the β-dependent current is high.

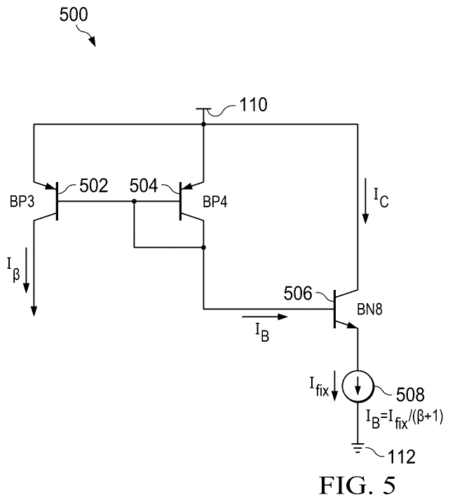

If the β-dependent current is less than the reference current (β is high), then the Z-setting circuit 302 provides a current (I_{β-high}) responsive to the β-dependent current to the collector of BN1 104 and does not provide a current at the emitter of BN1 104. In some examples, if the Z-setting circuit 302 provides I_{β-high} to the collector of BN1 104 and there is low or no load current, the amplifier 300 of FIG. 3 behaves like the amplifier 200 of FIG. 2, so that R_{IN} varies with β as shown in Equation 6. An example circuit for providing the β-dependent current is described with respect to FIG. 5.

Recall that gₘ equals collector current divided by thermal voltage, and the current provided by the current source 108 is constant. Thermal voltage is directly proportional to temperature. I_{β-high} and current to the collector of BN3 202 are also directly proportional to temperature. While β is high, base current is relatively small relative to collector and emitter currents, so that collector current approximately equals emitter current, so that the temperature dependencies of the respective collector currents and of the thermal voltage can be modeled as cancelling out. Accordingly, the amplifier 300 can be designed so that while beta is high, g_{mEF} and g_{mAUX} are constant in response to varying temperature.

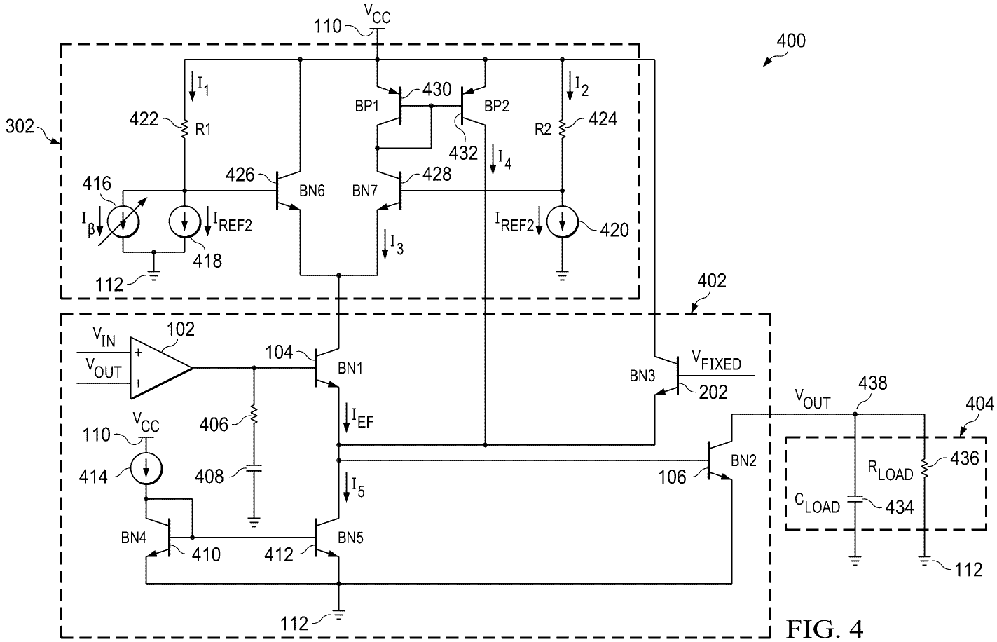

If the β-dependent current is greater than the reference current (β is low), then the Z-setting circuit 302 provides a first current responsive to the reference current to the collector of BN1 104 and provides a second current responsive to the reference current to the emitter of BN1 104. This results in the transconductance g_{mEF} of BN1 104 decreasing (as further described with respect to FIG. 4), which increases R_{IN}, as shown in Equation 6. In some examples, this increase in R_{IN} is achieved while increasing the DC loop gain of the amplifier 300, and without otherwise affecting stability of the amplifier 300.

FIG. 4 is a circuit diagram of an example amplifier system 400 with an amplifier 402 (such as an op-amp), an example implementation of the impedance-setting circuit 302, and a load 404. The voltage source 110 provides a voltage V_{CC}. The amplifier 402 includes a first resistor 406, a first capacitor 408, a fourth NPN BJT (BN4) 410, a fifth NPN BJT (BN5) 412, and a first fixed current source 414.

The impedance-setting stage 302 includes a second variable current source (I_{β}) 416 that provides a β-dependent current I_{β}, a third fixed current source (I_{REF1}) 418 that provides a first reference current I_{REF1}, a fourth fixed current source (I_{REF2}) 420 that provides a second reference current I_{REF2}, a second resistor 422 with resistance R1, a third resistor 424 with resistance R1, a sixth NPN BJT (BN6) 426, a seventh NPN BJT (BN7) 428, a first PNP BJT (BP1) 430, and a second PNP BJT (BP2) 432.

The load includes a load capacitor (C_{LOAD}) 434 with capacitance C_{LOAD}, and a load resistor (R_{LOAD}) 436 with resistance R_{LOAD}.

A noninverting input of the first stage 102 receives an input voltage V_{IN}, and an inverting input of the first stage 102 is coupled to an output node 438. In some examples, different connections are used to close the feedback loop in a correct polarity to maintain negative feedback. The output node 438 is coupled to a first terminal of the load 404 and has voltage V_{OUT}. A second terminal of the load 404 is coupled to ground 112. First terminals of C_{LOAD} 434 and R_{LOAD} 436 are coupled to the first terminal of the load 404, and second terminals of C_{LOAD} 434 and R_{LOAD} 436 are coupled to the second terminal of the load 404.

An output of the first stage 102 is coupled to a first terminal of the first resistor 406 and to the base of BN1 104. A second terminal of the first resistor 406 is coupled to a first terminal of the first capacitor 408. A second terminal of the first capacitor 408 is coupled to ground 112.

A collector of BN1 104 is coupled to emitters of BN6 426 and BN7 428. An emitter of BN1 104 is coupled to an emitter of BN3 202, collectors of BP2 432 and BN5 412, and a base of BN2 106. A collector of BN3 202 is coupled to the voltage source 110, and a base of BN3 202 receives a fixed bias voltage VFIXED. A collector of BN2 106 is coupled to the output node 438.

A collector and base of BN4 410 are coupled to a second terminal of the first current source 414 and the base of BN5 412. Accordingly, BN4 410 is diode-connected, so that BN4 410 and BN5 412 together form a current mirror. Emitters of BN2 106, BN4 410, and BN5 412 are coupled to ground 112. A first terminal of the first current source 414 is coupled to the voltage source 110.

First terminals of I_{β} 416 and I_{REF1} 418 are coupled to a second terminal of the second resistor 422 and a base of BN6 426. Second terminals of I_{β} 416 and I_{REF1} 418 are coupled to ground 112. A first terminal of the second resistor 422 and a collector of BN6 426 are coupled to the voltage source 110. Note that I_{REF2} pulls down the base of BN7 428. Accordingly, in some examples, I_{REF1} helps to prevent the base and collector of BN7 428 from becoming forward biased.

Emitters of BP1 430 and BP2 432 and a first terminal of the third resistor 424 are coupled to the voltage source 110. A base and a collector of BP1 430 are coupled to a base of BP2 432 and a collector of BN7 428. Accordingly, BP1 430 is diode-connected so that BP1 430 and BP2 432 form a current mirror. In some examples, a collector current of BP2 432 is proportional to a collector current of BP1 430.

A base of BN7 428 is coupled to a second terminal of the third resistor 424 and a first terminal of I_{REF2} 420. A second terminal of I_{REF2} 420 is coupled to ground 112.

A current through the second resistor 422 is I₁, and a current through the third resistor 424 is I₂. I₁ equals I_{β} plus I_{REF1}, and I₂ equals I_{REF2}. In some examples, currents to bases of BN6 426 and BN7 428 are sufficiently small that they can be ignored for purposes of Equations 7 and 8. Accordingly, a voltage V₁ at the base of BN6 426 is given by Equation 7, and a voltage V₂ at the base of BN7 428 is given by Equation 8:

$${V}_{1} = {V}_{CC} - {I}_{1} \times {R}_{1} = {V}_{CC} - ( {I}_{β} + {I}_{REF 1} ) \times {R}_{1} \qquad Equation 7$$

$${V}_{2} = {V}_{CC} - {I}_{2} \times {R}_{1} = {V}_{CC} - {I}_{REF 2} \times {R}_{1} \qquad Equation 8$$

As described above, if β is relatively high, then I_{β} (a first β-dependent current) is relatively low. Accordingly, if β is higher than a threshold, then V₁>V₂ and the Z-setting circuit 302 provides a current responsive to V₁ (a second β-dependent current) to the collector of BN1 104 via a collector-emitter path of BN6 426. The second β-dependent current corresponds to I_{β-high}, as discussed above with respect to FIG. 3.

If β is lower than the threshold, then V₁<V₂ and the Z-setting circuit 302 provides a first current (I₃) responsive to V₂ (accordingly, responsive to I_{REF2}) to the emitter of BN1 104 via a collector-emitter path of BN7 428, and a second current (I₄) responsive to V₂ via a collector-emitter path of BP2 432. I₄ is generated responsive to I₃ by the current mirror that includes diode-connected BP1 430 and BP2 432. In some examples, the current at the collector of BP2 432 is a multiple of (such as two times) the current at the collector of BP1 430.

The current mirror corresponding to diode-connected BN4 410 and BN5 412 mirrors the current provided by the first current source 414 to the collector of BN5 412, so that a current to the collector of BN5 412 is I₅. Note that the first current source 414 can be designed to linearly vary with temperature to enable g_{mEF} and g_{mAUX} to be constant in response to varying temperature regardless of β.

As described with respect to FIG. 3, if β is low, so that V1<V2, then provided by the Z-setting circuit 302 decrease the transconductance of BN1 104, which increases R_{IN}. Transconductance of a BJT equals the collector current of the BJT divided by the thermal voltage (V_{T}). In Equations 9, 10, and 11, n corresponds to a 1:n ratio of current (I₃) provided by the emitter of BP1 430 to current (I₄) provided by the emitter of BP2 432, and g_{mEF} is the transconductance of BN1 104. The base current of BN1 104, which is relatively small, is ignored for simplicity. Equation 9 relates g_{mEF} to Is while V1>V2, so that current passes through BN6 426 and not BN7 428, as shown:

$${g}_{mEF} = {I}_{5} / {V}_{T} \qquad Equation 9$$

Equations 10 and 11 relate I₃ to I₅ and g_{mEF} to I₅ while V1<V2, so that current (I₃) passes through BN7 428 and not BN6 426 and additional current (I₄) is provided by BP2 432, as shown:

$${I}_{5} = {I}_{3} + n \times {I}_{3} = {I}_{3} \times ( n + 1 ) \qquad Equation 10$$

$${g}_{mEF} = {I}_{5} / ( {V}_{T} \times ( n + 1 ) ) \qquad Equation 11$$

Accordingly, while β is low so that V1<V2, g_{mEF} is reduced by a factor of n+1 so that R_{IN} is increased.

A current provided by the emitter of BN1 104 is I_{EF} (emitter follower current). If V₁<V₂ then a current to the base of BN2 106 equals I_{EF}+I₄−I₅. In this example I_{EF} and I₅ are both responsive to the constant current I_{REF2}, and accordingly set a floor on a current to the base of BN2 106, which sets a floor on R_{IN} and accordingly on DC loop gain of the amplifier system 400. In some examples, use of the Z-setting circuit 302 improves a minimum DC loop gain of the amplifier system 400 by 10 decibels (dB).

In some examples, transistors of the amplifier system 400 of FIG. 4 operate either in cutoff mode or in saturation mode. For example, if β is high, then BN7 428, BP1 430, and BP2 432 operate in cutoff mode and BN6 426 operates in saturation mode. If β is low, then BN7 428, BP1 430, and BP2 432 operate in saturation mode and BN6 426 operates in cutoff mode.

FIG. 5 is a circuit diagram of a circuit 500 for generating a β-dependent current. The circuit 500 includes a third PNP BJT (BP3) 502, a fourth PNP BJT (BP4) 504, an eighth NPN BJT (BN8) 506, and a fifth fixed current source 508. The fifth current source 508 provides a current I_{fix}. An emitter of BP3 502 provides I_{β}. Emitters of BP3 502 and BP4 504, and a collector of BN8 506, are coupled to the voltage source 110.

BN8 506 is designed to have the same β as BN1 104 while the amplifier system 400 is in quiescent conditions, corresponding to no load current. This design criterion includes avoiding variation in fabrication process, device temperature, and current density. The emitter of BN8 506 is coupled to a first terminal of the fifth current source 508. A second terminal of the fifth current source 508 is coupled to ground 112. A current to the base of BN8 506 is I_{B}, and a current to the collector of BN8 506 is I_{C}, so that β=I_{C}/I_{B}.

The base of BP3 502 is coupled to the base and collector of BP4 504 and the base of BN8 506. Accordingly, BP4 504 is diode-connected, so that BP3 502 and BP4 504 form a current mirror. In some examples, a ratio of current (I_{β}) at an emitter of BP3 502 to current (I_{B}) at an emitter of BP4 504 is 1:1.

I_{fix} is the emitter current of BN8 506, so that I_{fix} equals I_{B} plus I_{C}. Accordingly, I_{fix}=I_{B}+β×I_{B}=I_{B}×(1+β), so that I_{B}=I_{fix}/(1+β). I_{B} is reflected across the current mirror with a 1:1 ratio, so that I_{β} equals I_{B}. Accordingly, as described above, I_{β} is inversely related to β.

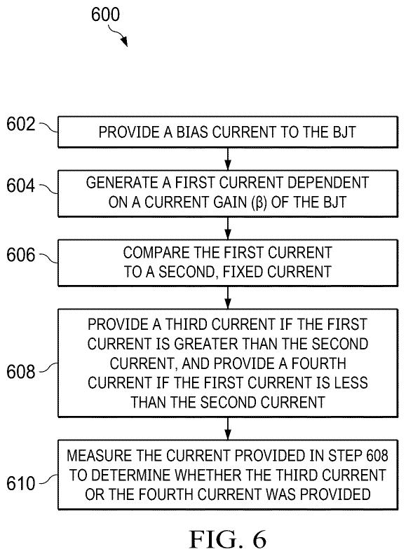

FIG. 6 is an example process 600 for detecting fabrication process variation in a BJT, such as BN1 104. In block 602, provide a bias current to the BJT. In an example, the input stage 102 provides the bias current to BJT BN1 104. In block 604, generate a first current dependent on a current gain (β) of the BJT. In an example, circuit 500 generates the first current (the β-dependent current). In block 606, compare the first current to a second, fixed current. The second current corresponds to a threshold value of β. In an example, the fourth fixed current source 420 provides I_{REF2} as the second current, and the comparison corresponds to whether current is steered through BN6 426 or BN7 428. In block 608, provide a third current if the first current is greater than the second current, and provide a fourth current if the first current is less than the second current. In some examples, the third current corresponds to current provided by the emitter of BN6 426, and the fourth current corresponds to current provided by the emitter of BN7 428.

Comparing the first current to the second current corresponds to comparing β to the threshold value. In some examples, the comparison of block 606 is performed as a comparison between voltages, or other signal comparison. In some examples, either the third current or the fourth current is a zero current (zero Amperes).

In block 610, measure the current provided in block 608 to determine whether the third current or the fourth current was provided. In some examples, the process 600 can be used during a device test process or during deployment of a corresponding device to facilitate configuration of a device that includes the BJT. In some examples, the first current is compared to multiple different second currents to determine a range for B.

In some examples, an impedance-setting circuit 302 can also be used with other circuits that use an emitter follower BJT and that are subject to process variation and/or temperature variation.

In some examples, a resistance R2 of the third resistor 424 is different from a resistance R1 of the second resistor 422, such as R2=2×R1.

In some examples, current gains of different transistors are different.

In some examples, transistors are designed so that transconductance varies in response to varying temperature.

The term “couple” is used throughout the specification. The term may cover connections, communications, or signal paths that enable a functional relationship consistent with this description. For example, if device A provides a signal to control device β to perform an action, in a first example device A is coupled to device B, or in a second example device A is coupled to device β through intervening component C if intervening component C does not substantially alter the functional relationship between device A and device β such that device β is controlled by device A via the control signal provided by device A.

In this description, the term “and/or” (when used in a form such as A, β and/or C) refers to any combination or subset of A, B, C, such as: (a) A alone; (b) β alone; (c) C alone; (d) A with B; (e) A with C; (f) β with C; and (g) A with β and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin”, “ball” and “lead” are used interchangeably. Unless specifically stated to the contrary, these terms are generally used to mean an interconnection between or a terminus of a device element, a circuit element, an integrated circuit, a device or other electronics or semiconductor component.

While certain elements of the described examples may be included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described examples, and other examples are possible within the scope of the claims.

What is claimed is:

1. A circuit comprising:
a first current source having first and second terminals;
a second current source having first and second terminals;
a first bipolar junction transistor (BJT) having a collector, an emitter, and a base;
a second BJT having a collector, an emitter, and a base, the base of the second BJT coupled to the first terminal of the first current source;
a third BJT having a collector, an emitter, and a base, the base of the third BJT coupled to the first terminal of the second current source, and the emitter of the third BJT coupled to the emitter of the second BJT and the collector of the first BJT;
a fourth BJT having a collector, an emitter, and a base; and
a fifth BJT having a collector, an emitter, and a base, the base of the fifth BJT coupled to the base and emitter of the fourth BJT and to the collector of the third BJT, and the collector of the fifth BJT coupled to the emitter of the first BJT.

2. The circuit of claim 1,
wherein the first current source is configured to provide a first current that is responsive to a current to the base of the first BJT and a current to the collector of the first BJT; and
wherein the second current source is configured to provide a second current that is constant.

3. The circuit of claim 1, further comprising a sixth BJT having a collector, an emitter, and a base, the emitter of the sixth BJT coupled to the emitter of the first BJT.

4. The circuit of claim 1, wherein the collector of the second BJT is coupled to the emitters of the fourth and fifth BJTs.

5. The circuit of claim 1, wherein the first current source includes:
a third current source having a first terminal and a second terminal;
a sixth BJT having a collector, an emitter, and a base, the second terminal of the sixth BJT coupled to the second terminal of the first current source;
a seventh BJT having a collector, an emitter, and a base; and
an eighth BJT having a collector, an emitter, and a base, the base of the eighth BJT coupled to the bases of the sixth and seventh BJTs and to the collector of the seventh BJT, the emitter of the eighth BJT coupled to the first terminal of the third current source, and the collector of the eighth BJT coupled to the emitters of the sixth and seventh BJTs and to the first terminal of the first current source.

6. The circuit of claim 1, further comprising:
a resistor having first and second terminals, the first terminal of the resistor coupled to the base of the first BJT; and
a capacitor having first and second terminals, the first terminal of the capacitor coupled to the second terminal of the resistor.

7. The circuit of claim 1, further comprising:
a third current source having first and second terminals;
a sixth BJT having a collector, an emitter, and a base; and
a seventh BJT having a collector, an emitter, and a base, the base of the seventh BJT coupled to the collector and base of the sixth BJT and the first terminal of the third current source, and the collector of the seventh BJT coupled to the emitter of the first BJT.

8. The circuit of claim 1, further comprising:
a first resistor having first and second terminals, wherein the base of the second BJT is coupled to the first terminal of the first resistor;
a second resistor having first and second terminals, wherein the base of the third BJT is coupled to the first terminal of the second resistor.

9. A circuit comprising:
a first stage including an input and an output;
a second stage including:
a first current source having first and second terminals;
a second current source having first and second terminals;
a first bipolar junction transistor (BJT) having a collector, an emitter, and a base, the base of the first BJT coupled to the output of the first stage;
a second BJT having a collector, an emitter, and a base, the base of the second BJT coupled to the first terminal of the first current source;
a third BJT having a collector, an emitter, and a base, the base of the third BJT coupled to the first terminal of the second current source, and the emitter of the third BJT coupled to the emitter of the second BJT and the collector of the first BJT;
a fourth BJT having a collector, an emitter, and a base; and
a fifth BJT having a collector, an emitter, and a base, the base of the fifth BJT coupled to the base and emitter of the fourth BJT and to the collector of the third BJT, and the collector of the fifth BJT coupled to the emitter of the first BJT; and
a third stage including an input and an output, the input of the third stage coupled to the emitter of the first BJT, and the output of the third stage coupled to the input of the first stage.

10. The circuit of claim 9, further comprising:
a first resistor having first and second terminals, wherein the base of the second BJT is coupled to the first terminal of the first resistor;
a second resistor having first and second terminals, wherein the base of the third BJT is coupled to the first terminal of the second resistor.

11. The circuit of claim 9,
wherein the first current source is configured to provide a first current that is responsive to a current to the base of the first BJT and a current to the collector of the first BJT; and
wherein the second current source is configured to provide a second current that is constant.

12. The circuit of claim 9, further comprising a sixth BJT having a collector, an emitter, and a base, the emitter of the sixth BJT coupled to the emitter of the first BJT.

13. The circuit of claim 9, wherein the collector of the second BJT is coupled to the emitters of the fourth and fifth BJTs.

14. The circuit of claim 9, wherein the first current source includes:
a third current source having a first terminal and a second terminal;
a sixth BJT having a collector, an emitter, and a base, the second terminal of the sixth BJT coupled to the second terminal of the first current source;
a seventh BJT having a collector, an emitter, and a base; and
an eighth BJT having a collector, an emitter, and a base, the base of the eighth BJT coupled to the bases of the sixth and seventh BJTs and to the collector of the seventh BJT, the emitter of the eighth BJT coupled to the first terminal of the third current source, and the collector of the eighth BJT coupled to the emitters of the sixth and seventh BJTs and to the first terminal of the first current source.

15. The circuit of claim 9, wherein the first stage is a differential transconductance amplifier.

16. A circuit comprising:
a emitter follower-connected (EFC) bipolar junction transistor (BJT) having a collector, an emitter, and a base; and
an impedance-setting circuit having a first terminal, a second terminal, and a third terminal, the first terminal of the impedance-setting circuit coupled to the collector of the EFC BJT, and the second terminal of the impedance-setting circuit coupled to the emitter of the EFC BJT;
wherein the impedance-setting circuit is configured to compare a first current to a threshold, and to, responsive to the comparison, either provide a second current to the collector of the EFC BJT or provide a third current to the collector of the EFC BJT and provide a fourth current to the emitter of the EFC BJT.

17. The IC of claim 16,
wherein the threshold corresponds to a reference current; and
wherein the first current is responsive to a current at the base of the EFC BJT and a current at the collector of the EFC BJT.

18. The IC of claim 17,
wherein the second current is responsive to the first current; and
wherein the third current and the fourth current are responsive to the reference current.

19. The IC of claim 17,
wherein the impedance-setting circuit includes a second BJT having a current path, and includes a current mirror having first and second terminals;
wherein the current path of the second BJT is coupled between the collector of the EFC BJT and the first terminal of the current mirror; and
wherein the second terminal of the current mirror is coupled to the emitter of the EFC BJT.

20. The IC of claim 16, further comprising an output stage having a control terminal coupled to the emitter of the EFC BJT.
